(19) United States
(12) Patent Application Publication
(10) Pub. No.: US 2007/0284677 A1
(43) Pub. Date: Dec. 13, 2007

(54) Metal oxynitride gate

(76) Inventors: Weng Chang, Hsin-Chu (TW); Boq-Kang Hu, Tainan (TW); Jamie Schaeffer, Austin, TX (US); David C. Gilmer, Austin, TX (US); Phil Tobin, Austin, TX (US)

Correspondence Address: SLATER & MATSIL, L.L.P., 17950 PRESTON ROAD, SUITE 1000, DALLAS, TX, 75252, US

(21) Appl. No.: 11/796,164

(22) Filed: Apr. 26, 2007

Related U.S. Application Data
(60) Provisional application No. 60/811,820, filed on Jun. 8, 2006.

(51) Int. Cl. H01L 29/76; H01L 21/336

(52) U.S. Cl. 257/412; 438/303; 257/E29.226; 257/E21.409

(57) ABSTRACT

A metal-oxide-semiconductor (MOS) transistor having a gate electrode comprising a metal oxynitride and a method of forming the same are provided. The metal oxynitride preferably comprises molybdenum oxynitride and/or iridium oxynitride. The gate electrode may further comprise carbon and/or silicon. The gate electrode is preferably formed in a chamber containing nitrogen, oxygen and a carbon-containing gas. The gate electrode of the MOS transistor has a high work function and a low equivalent oxide thickness.

This application claims the benefit of Provisional Patent Application Ser. No. 60/811,820, filed Jun. 8, 2006, and entitled “Metal Oxynitride Gate,” which application is incorporated herein by reference.

### TECHNICAL FIELD

This invention relates generally to semiconductor devices, and more particularly to metal-oxide-semiconductor (MOS) devices.

### BACKGROUND

Metal-oxide-semiconductor (MOS) transistors are basic building elements in integrated circuits. An example of a conventional MOS transistor structure is shown in FIG. 1. A MOS transistor 2 typically includes a gate dielectric 8, a gate electrode 4, source/drain regions 6, and gate spacers 10. The top surfaces of source/drain regions 6 and gate electrode 4 are typically silicided, forming silicides 12 and 14 respectively.

In a conventional MOS transistor as shown in FIG. 1, the gate electrode 4 typically comprises polysilicon doped with p-type or n-type impurities, using doping operations such as ion implantation or thermal diffusion. It is preferred to adjust the work function of the gate electrode 4 to the band-edge of silicon; that is, for NMOS transistors, adjust work functions close to the conduction band, and for PMOS transistors, adjust work functions close to the valence band. Adjusting the work function of the polysilicon gate electrode 4 can be achieved by selecting appropriate impurities.

MOS transistors with polysilicon gate electrodes exhibit a carrier depletion effect, also referred to as a poly depletion effect. The poly depletion effect occurs when an applied electric field sweeps away carriers from a region close to the gate dielectric 8, forming a depletion layer. In n-doped polysilicon, the depletion layer includes ionized non-mobile donor sites, whereas in p-doped polysilicon, the depletion layer includes ionized non-mobile acceptor sites. The depletion effect increases the effective gate dielectric thickness, making it more difficult for an inversion layer to be created at the surface of the semiconductor.

The use of thinner gate dielectrics tends to make the carrier depletion effect even worse. With thinner gate dielectrics, the depletion layer in the polysilicon gate becomes more significant in dimension when compared to the thickness of the thin gate dielectric, and thus device performance degradation is worsened. As a result, the carrier depletion effect in the gate electrode limits device scalability by imposing a lower bound on how much the effective gate dielectric thickness can be reduced.

The poly depletion effect was previously solved by using metal gate electrodes or metal silicide gate electrodes. For PMOS transistors, different materials including transition metal, metal alloy, metal nitride and metal silicide have been evaluated. However, most of these materials still have difficulty achieving an effective work function higher than 5 eV. Although metal nitride gates having high work functions have been reported, it is difficult to adjust the work function of metal nitrides to the band-edge and further improve PMOS transistor performance. For example, U.S. Patent Application No. 2003/0146479 discusses a gate electrode for PMOS that uses tantalum nitride, which has a work function of about 5.4 eV. A similar gate electrode was also discussed in U.S. Patent Application No. 2003/0129793, wherein a composite gate electrode structure including titanium nitride and tantalum nitride is discussed.

Therefore, there is a need for gate electrode materials having band-edge work functions and methods for adjusting the work functions.

### SUMMARY OF THE INVENTION

The preferred embodiment of the present invention provides a PMOS transistor having a gate electrode comprising metal oxynitride.

In accordance with one aspect of the present invention, the metal oxynitride preferably includes molybdenum oxynitride and/or iridium oxynitride. The gate electrode may further include carbon and/or silicon. The gate electrode of the preferred embodiment can have a band-edge work function.

In accordance with another aspect of the present invention, a method embodiment includes forming a gate electrode layer comprising a metal oxynitride over a semiconductor substrate and patterning the gate electrode layer to form a gate electrode. The preferred methods for forming the gate electrode layer include physical vapor deposition (PVD), atomic layer deposition (ALD), chemical vapor deposition (CVD) such as plasma enhanced chemical vapor deposition (PECVD), metal-organic physical vapor deposition (MOCVD), molecular beam epitaxy (MBE), and the like. Preferably, the gate electrode layer is formed in a chamber containing nitrogen and oxygen. The chamber may further contain a carbon-containing gas such as CH₄. Silicon may be further added into the gate electrode by using a metal silicide sputtering target.

In accordance with another aspect of the present invention, the composition of the metal oxynitride can be changed by adjusting the partial pressures of nitrogen, oxygen and carbon-containing gas. The work function of the gate electrode is thus changed, and a band-edge work function can be achieved.

A metal oxynitride gate electrode will have a high work function. The work function can be adjusted to band-edge by selecting a proper composition. The equivalent oxide thickness of the preferred embodiments of the present invention is significantly lower than that of the transistor using a metal oxide gate. Therefore, high performance can be achieved on PMOS transistors using a metal oxynitride gate electrode.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a conventional MOS transistor;

FIGS. 2 through 6 are cross-sectional views of intermediate stages in the manufacture of a PMOS transistor embodiment; and

FIG. 7 illustrates a comparison of the equivalent oxide thicknesses of iridium oxide and molybdenum oxynitride.

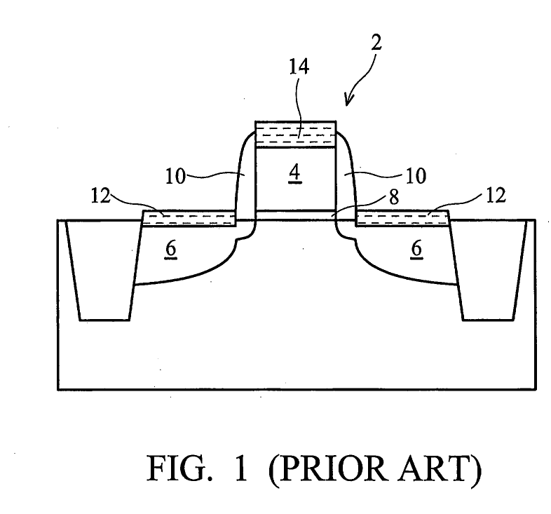

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

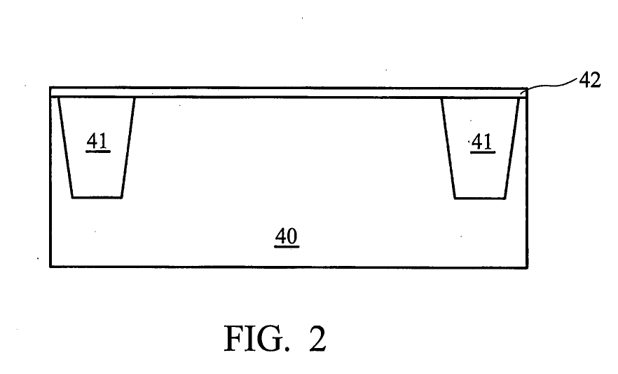

FIGS. 2 through 6 illustrate cross-sectional views of a preferred embodiment of the present invention, wherein a PMOS transistor is formed. Referring to FIG. 2, a gate dielectric layer 42 is formed on a substrate 40, which comprises shallow trench isolation regions 41. The substrate 40 may comprise commonly used substrate materials such as silicon, strained silicon on SiGe, silicon on insulator (SOI), silicon germanium on insulator (SGOI), and the like. The substrate 40 may also have a composite structure such as a silicon-on-oxide structure. The substrate 40 is preferably lightly doped.

In the preferred embodiment, the gate dielectric layer 42 has a high dielectric constant (k value), preferably greater than about 3.9. It preferably comprises materials selected from the group consisting of SiO₂, SiOₓN_{y}, oxynitrides formed from transition metals, nitrides, and dielectric metal oxides, such as HfO₂, HfZrOₓ, HfSiOₓ, HfTiOₓ, HfAlOₓ, Al₂O₃, La₂O₃, TiO₂, Ta₂O₅, ZrO₂, and the like. In other embodiments, the gate dielectric layer 42 has a composite structure having more than one layer, such as an oxide-nitride-oxide (ONO) structure. Each of the dielectric layers in the composite structure may comprise materials selected from the above-discussed materials. The preferred methods for forming the gate dielectric layer 42 include commonly used physical vapor deposition (PVD) techniques, chemical vapor deposition (CVD) techniques such as low temperature CVD (LTCVD), low pressure CVD (LPCVD), rapid thermal CVD (RTCVD), plasma enhanced CVD (PECVD), metal-organic physical vapor deposition (MOPVD), as well as other methods such as atomic layer deposition (ALD) and molecular beam epitaxy (MBE), etc.

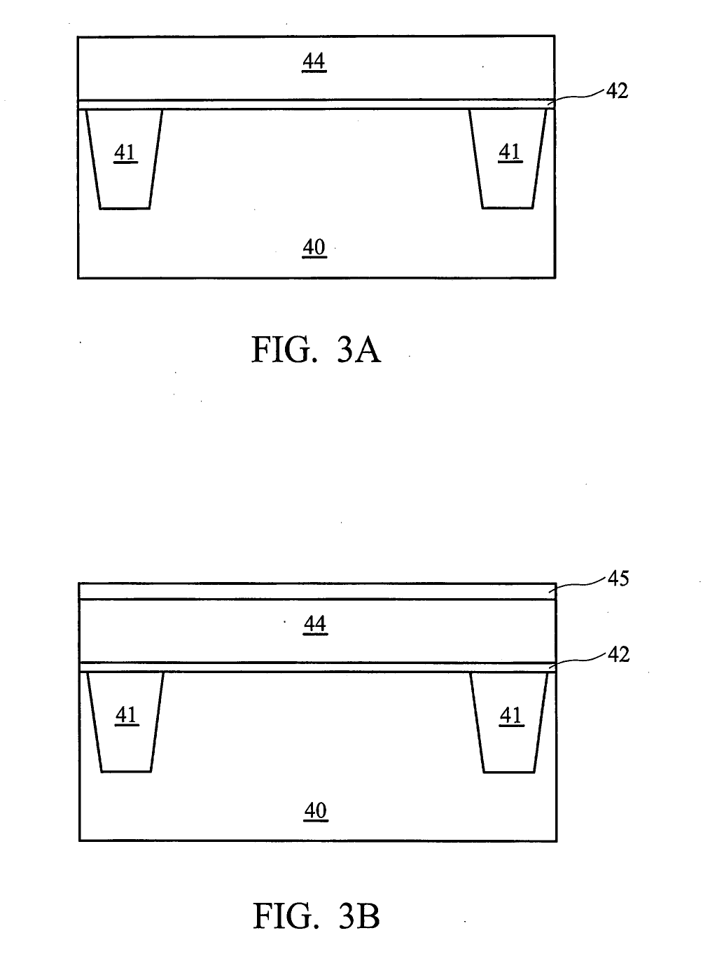

A gate electrode layer 44 is then formed on the gate dielectric layer 42, as shown in FIG. 3A. The gate electrode layer 44 can be in the form of a single layer or a multilayer. For a single layer gate electrode, the gate electrode layer 44 preferably comprises a metal oxynitride or a combination of metal oxynitrides formed using transition metals such as Mo, Ir, Ta, Ti, W, Hf, Ru, Al, Nb, and the like. For a multilayer gate electrode, at least one layer, but not limited to only one layer, within the gate electrode 44 preferably comprises a metal oxynitride or a combination of metal oxynitrides formed from transition metals such as Mo, Ir, Ta, Ti, W, Hf, Ru, and the like. In the preferred embodiment, the gate electrode layer 44 is deposited using physical vapor deposition (PVD). In other embodiments, the gate electrode layer 44 is formed using a chemical vapor deposition (CVD) method, such as a plasma enhanced CVD, metal-organic CVD, and the like. In yet other embodiments, other commonly used deposition methods such as atomic layer deposition (ALD) and molecular beam epitaxy (MBE) can be used.

The formation of the gate electrode layer 44 is preferably performed in a pressure-controllable chamber. A metal, such as molybdenum, or a metal alloy, is used as a sputtering target, from which the metal is deposited. The chamber preferably comprises nitrogen and oxygen and has a pressure of between about 1 milli-Torr and about 20 Torr for a physical vapor deposition (PVD) method. The chamber may further include a carbon-containing gas, such as CH₄.

Since the gases in the chamber contain nitrogen and oxygen, the resulting gate electrode layer 44 comprises a metal oxynitride, which can be expressed as MOₓN_{y}, wherein M symbolizes a metal or metal alloy. For molybdenum oxynitride and iridium oxynitride, x is preferably in a range between about 0.05 and about 2, and y is preferably in a range between about 0.05 and about 1. The metal oxynitride preferably has a high work function of greater than about 4.95 eV, and more preferably greater than about 5 eV.

Typically, oxygen has a high electronegativity, and more oxygen in the metal oxynitride results in increased work function. Nitrogen, on the other hand, has a lower electronegativity than oxygen. Therefore, more nitrogen results in a lowered work function. By selecting an appropriate metal and adjusting the composition of nitrogen and oxygen, a band-edge work function, in which the work function is substantially close to the valence band for PMOS transistors, can be achieved.

The composition of oxygen and nitrogen can be adjusted by adjusting the partial gas pressures of nitrogen and oxygen, respectively. Typically, increasing the flow rate of oxygen and nitrogen will increase the x and y values in MOₓN_{y}, respectively. The partial gas pressures can be controlled by adjusting respective flow rates of the oxygen and nitrogen. One skilled in the art will be able to find an optimum setting for the formation process in order to achieve a band-edge work function.

The introduction of carbon-containing gases adds carbon into the gate electrode layer 44, forming carbon containing metal oxynitride, which can be expressed as MOₓN_{y}C_{z}. The value of z is preferably in a range between about 0.05 and about 1. Carbon has an even lower electronegativity than nitrogen and oxygen. The addition of carbon further strengthens the ability to adjust the work function of gate electrode layer 44 from the valence band edge to the conduction band edge.

The gate electrode layer 44 may further include silicon in addition to metal, nitrogen, oxygen, and carbon. Preferably, by using a sputtering target comprising both silicon and metal, the gate electrode layer 44 can comprise both metal and silicon. The preferred target may include molybdenum silicide, iridium silicide, nickel silicide, titanium silicide, cobalt silicide, tungsten silicide, and combinations thereof.

By using the preferred embodiment of the present invention, a work function of about 5 eV has been observed on a molybdenum oxynitride (MoOₓN_{y}) gate.

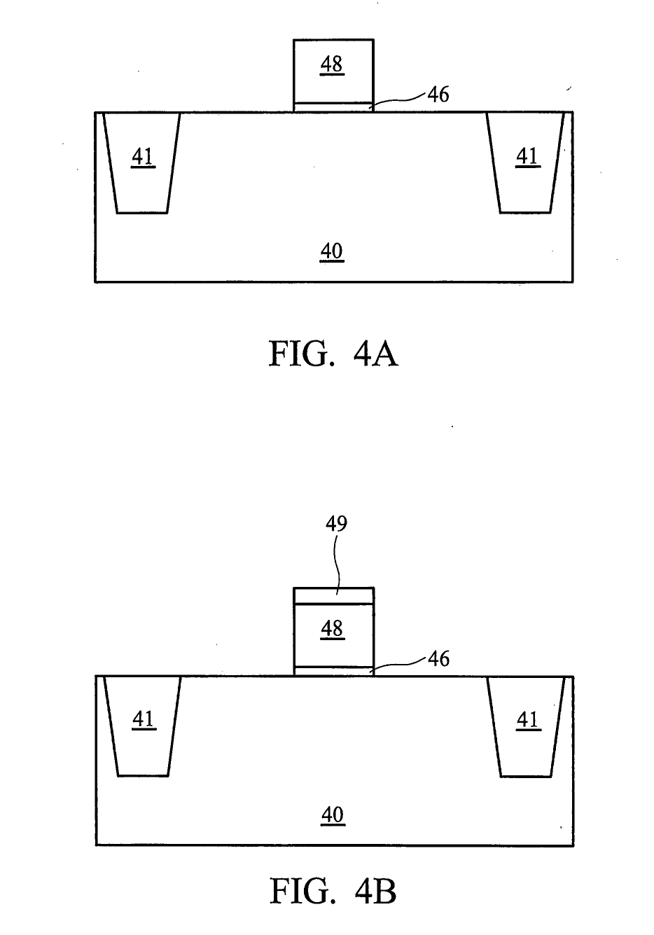

Referring to FIG. 4A, the gate dielectric layer 42 and gate electrode layer 44 are patterned, forming gate dielectric 46 and gate electrode 48, respectively. Both dry and wet etches can be used for the patterning of the gate dielectric 46 and the gate electrode 48.

An alternative embodiment is shown in FIGS. 3B and 4B, wherein a polysilicon cap is further formed on the gate electrode 48. Referring to FIG. 3B, a polysilicon layer 45 is formed capping the gate electrode layer 44. In FIG. 4B, polysilicon layer 45 is patterned along with the gate dielectric layer 42 and gate electrode layer 44, and a polysilicon cap 49 is formed.

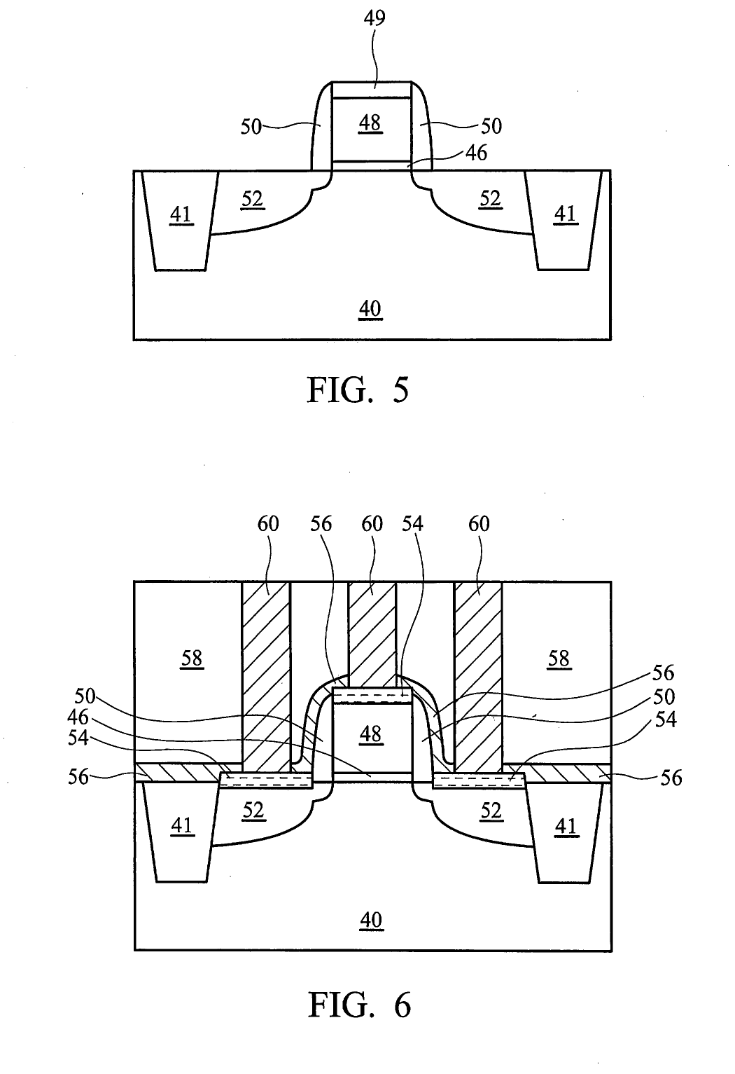

FIG. 5 illustrates the formation of gate spacers 50 and source/drain regions 52. As is known in the art, the gate spacers 50 can be formed by blanket depositing a dielectric layer, such as SiN, and then etching undesired portions. In the preferred embodiment, the source/drain regions 52 are formed by implanting P-type impurities into the semiconductor substrate 40 for PMOS. The gate spacers 50 are used as a mask during implanting so that the edges of the source/drain regions 52 are substantially aligned with the respective gate spacers 50.

The source/drain regions 52 are preferably activated by a subsequent anneal at a temperature of above 1000° C. in a nitrogen-containing environment, although different anneal parameters can be taken. In addition to the anneal for source/drain activation, a further anneal is typically performed for the formation of the subsequently formed source/drain silicide regions. Due to the elevated temperature during annealing processes, oxygen in the gate electrode diffuses to the silicon region, thus increasing the silicon oxide thickness in an interfacial layer between the gate dielectric 46 and the underlying silicon 40. The equivalent oxide thickness (EOT), which shows an equivalent thickness of SiO₂ gate oxide needed to obtain the same gate capacitance as the one obtained from a gate dielectric featuring a higher k value, increases. However, smaller EOT increments are observed on the preferred embodiments of the present invention as a result of the anneal.

FIG. 6 illustrates a structure after the formation of silicides 54, a contact etch stop layer (CESL) 56, an inter-layer dielectric (ILD) 58, and contact plugs 60. To form the silicides 54, a thin layer of metal (not shown), such as cobalt, nickel, erbium, molybdenum, platinum, or the like, is first formed over the device. The device is then annealed to form silicides 54 between the deposited metal and the underlying exposed silicon regions. The remaining metal layer is then removed. The CESL 56 is preferably blanket deposited. This layer serves two purposes. First, it provides a stress to the device and enhances carrier mobility. Second, it protects underlying regions from being over etched. Next, the ILD 58 is deposited over CESL 56. The contact plugs 60 are then formed. The processes of forming such are well known in the art and therefore are not repeated herein.

The preferred embodiments of the present invention have several advantageous features. Metal oxynitride gates have the potential of having higher work functions due to the existence of oxygen. By adjusting the composition, work functions can be tuned to band-edge. High performance PMOS devices can therefore be obtained with less difficulty. For device integration under similar thermal conditions, the equivalent oxide thickness (EOT) of a metal oxynitride gate electrode can be kept lower than the EOT of an oxide gate electrode which contributes to the high performance of the MOS device.

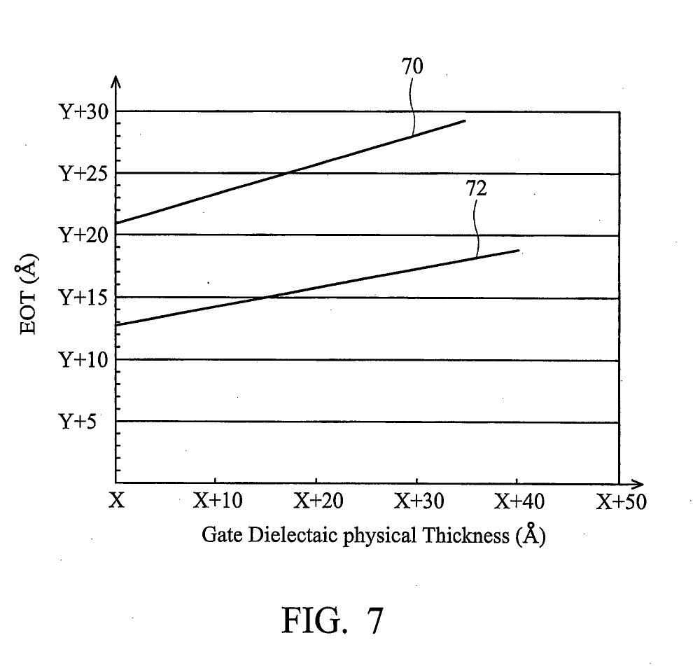

FIG. 7 is illustrated to compare equivalent oxide thicknesses of iridium oxide and molybdenum oxynitride, wherein “x+” and “y+” indicate relative values instead of absolute values. Lines 70 and 72 illustrate the EOTs of an iridium oxide gate and a molybdenum oxynitride gate as functions of the physical thicknesses of the gate dielectrics, which are formed of HfO₂. Both iridium oxide and molybdenum oxynitride can reach work functions of about 5 eV. However, the EOT of molybdenum oxynitride is significantly less than that of the iridium oxide. Additionally, when the physical thickness of the gate dielectric increases, the EOT of molybdenum oxynitride increases a significantly lesser amount than the EOT of iridium oxide. For example, when the physical thickness of the gate dielectric increases for about 20 Å, the iridium oxide has an EOT increment of about 5.5 Å, while molybdenum oxynitride has an EOT increment of only about 3 Å.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A metal-oxide-semiconductor (MOS) transistor comprising a gate electrode over a semiconductor substrate, wherein the gate electrode comprises a metal oxynitride.

2. The MOS transistor of claim 1 wherein the metal oxynitride comprises molybdenum oxynitride.

3. The MOS transistor of claim 1 wherein the metal oxynitride comprises iridium oxynitride.

4. The MOS transistor of claim 1 wherein the metal oxynitride comprises a metal selected from the group consisting essentially of Ta, Ti, W, Hf, Ru, Al, Nb, and combinations thereof.

5. The MOS transistor of claim 1 wherein a ratio of atomic number of metal to atomic number of oxygen in the metal oxynitride is between about 0.05 and about 2.

6. The MOS transistor of claim 1 wherein a ratio of atomic number of metal to atomic number of nitrogen in the metal oxynitride is between about 0.05 and about 1.

7. The MOS transistor of claim 1 wherein the gate electrode further comprises carbon.

8. The MOS transistor of claim 7 wherein a ratio of atomic number of metal to atomic number of carbon in the metal oxynitride is between about 0.05 and about 1.

9. The MOS transistor of claim 1 wherein the gate electrode further comprises silicon.

10. The MOS transistor of claim 1 wherein the gate electrode comprises a single layer.

11. The MOS transistor of claim 1 wherein the gate electrode comprises more than one layer, and wherein at least one of the more than one layers comprises a metal oxynitride formed using a metal selected from the group consisting essentially of Mo, Ir, Ta, Ti, W, Hf, Ru, Al, Nb, and combinations thereof.

12. The MOS transistor of claim 1 further comprising:
a gate dielectric over the semiconductor substrate and underlying the gate electrode;
a gate spacer on a sidewall of the gate dielectric and the gate electrode; and
a source/drain region substantially aligned with a sidewall of the gate spacer.

13. The MOS transistor of claim 12 wherein the gate dielectric has a k value of greater than about 3.9.

14. A method of forming a MOS transistor, the method comprising:
forming a gate electrode layer comprising a metal oxynitride over a semiconductor substrate; and
patterning the gate electrode layer to form a gate electrode.

15. The method of claim 14 wherein the step of forming the gate electrode layer comprises physical vapor deposition.

16. The method of claim 14 wherein the step of forming the gate electrode layer comprises a method selected from the group consisting essentially of chemical vapor deposition, atomic layer deposition (ALD), molecular beam epitaxy, and combinations thereof.

17. The method of claim 14 wherein the step of forming the gate electrode is performed in a chamber comprising nitrogen and oxygen.

18. The method of claim 17 wherein the step of forming the gate electrode comprises adjusting flow rates of nitrogen and oxygen to adjust the composition of the metal oxynitride.

19. The method of claim 17 wherein the chamber further comprises a carbon-containing gas.

20. The method of claim 19 wherein the carbon-containing gas comprises CH₄.

21. The method of claim 14 wherein the gate electrode layer comprises silicon.

22. The method of claim 21 wherein the gate electrode layer is deposited using a sputtering target comprising silicon.

23. The method of claim 14 further comprising:
forming a gate dielectric layer over the semiconductor substrate and underlying the gate electrode layer;
patterning the gate dielectric layer and the gate electrode layer to form a gate dielectric and a gate electrode, respectively;
forming a gate spacer on a sidewall of the gate dielectric and the gate electrode; and
forming a source/drain region substantially aligned with a sidewall of the gate spacer.
